(19) United States
(12) Patent Application Publication
(10) Pub. No.: US 2001/0001742 A1
(43) Pub. Date: May 24, 2001

(54) METHOD OF FABRICATING A DUAL -DAMASCENE STRUCTURE IN AN INTEGRATED CIRTCUIT WITH MULTILEVEL-INTERCONNECT STRCTURE

(76) Inventors: YIMIN HUANG, TAICHUNG HEIEN (TW); TRI-RUNG YEW, HSINCHU HEIEN (TW)

Correspondence Address: DANIEL R MCCLURE, THOMAS KAYDEN HORSTEMEYER & RISLEY, SUITE 1500, 100 GALLERIA PARKWAY N W, ATLANTA, GA, 30339

(21) Appl. No.: 09/215,073

(22) Filed: Dec. 18, 1998

(30) Foreign Application Priority Data
Oct. 2, 1998 (TW) 87116432

(51) Int. Cl. H01L 21/302; H01L 21/461

(52) U.S. Cl. 438/710

(57) ABSTRACT

A semiconductor fabrication method is provided for the fabrication of a dual-damascene structure in an integrated circuit with a multilevel-interconnect structure. This method is characterized in that, after the dual-damascene hole is formed, a conformal barrier/adhesive layer is first formed over all the sidewalls of the dual-damascene hole, but not filling the dual-damascene hole. An anisotropic etching process is then performed to etch away the part of the conformal barrier/adhesive layer that is laid at the bottom of the dual-damascene hole and subsequently the underlying part of the topping layer until exposing the metallization layer. Finally, a conductive material, such as copper, is deposited into the remaining void portion of the dual-damascene hole. The deposited conductive material and the remaining part of the conformal barrier/adhesive layer in the dual-damascene hole in combination constitute the intended dual-damascene structure. The conformal barrier/adhesive layer serves as a diffusion protective layer for the dielectric layers, which can subsequently help prevent diffusion of the spluttering metal atoms from the metallization layer during the RIE (Reaction Ion Etching) process into the dielectric layers.

### BACKGROUND OF THE INVENTION

1. Field of the Invention

This invention relates to semiconductor fabrication technology, and more particularly, to a method of fabricating a dual-damascene structure in an integrated circuit with multilevel-interconnect structure.

2. Description of Related Art

High-density integrated circuits are typically constructed on a multilevel interconnect structure including two or more levels of circuit layers to allow more transistor elements to be integrated in the same chip. A multilevel-interconnect structure includes two or more metallization layers that are physically separated by inter-metal dielectric (IMD) layers, with neighboring levels of metallization layers being electrically interconnected through metal plugs (also known as vias) formed in the IMD layer therebetween. A conventional method for fabricating a multilevel-interconnect structure includes a first step of forming a first-level metallization layer, a second step of forming an IMD layer over the first-level metallization layer, a third step of forming a metal plug at a predefined location in the IMD layer, which is electrically connecting to the first-level metallization layer, and a final step of forming a second-level metallization layer over the IMD layer. More levels of metallization layers can be formed over the second level metallization layer to constitute a multilevel-interconnect structure.

In the foregoing method, the metal plug and the overlying metallization layer are formed separately through different steps. A conventional method, called dual damascene technology, allows the metal plug and the overlying metallization layer to be formed together in one deposition step.

This technology is characterized in that a horizontally-extending trench and a vertically-extending via hole are formed together in the same IMD layer, and then a metal is deposited into the trench and the via hole, with the deposited metal in the via hole serving as the metal plug and the deposited metal in the trench serving as the overlying metallization layer. The combined structure of the metal plug and the overlying metallization layer is referred to as a dual-damascene structure. This technology allows the fabrication of the multilevel-interconnect structure to be less complex and thus easier and more cost effective

A conventional method for fabricating a dual-damascene structure in an integrated circuit is depicted in details in the following with reference to FIGS. 1A-1E.

Referring first to FIG. 1A, in the first step, a semiconductor substrate 100 is prepared. Then, a first-level metallization layer 102 is formed, preferably from copper, at a predefined location in the substrate 100. Next, a first topping layer 104 is formed over the substrate 100 to cover the metallization layer 102 for the purpose of preventing the diffusion of the metal atoms in the metallization layer 102 into the subsequently formed dielectric layer (i.e., the dielectric layer 106 shown in FIG. 1B).

Referring next to FIG. 1B, in the subsequent step, a thick dielectric layer 106 is formed over the first topping layer 104. Next, a selective removal process is performed to form an dual-damascene hole 107 in the dielectric layer 106 to expose the part of the first topping layer 104 that is laid directly above the metallization layer 102. This selective removal process is a conventional technique so the steps thereof are not detailed. The dual-damascene hole 107 has a wide upper part 114 for forming a second-layer metallization layer therein and a narrow bottom part 112 for forming a metal plug therein. Since the second-level metallization layer and the metal plug are formed together, the combined structure thereof is hence referred to as dual-damascene structure).

Referring further to FIG. 1C, in the subsequent step, an anisotropic etching process, such as an RIE (Reaction Ion Etching) process, is performed to etch away the exposed part of the first topping layer 104 until the metallization layer 102 is exposed. Through this process, the narrow bottom part 112 of the dual-damascene hole 107 is further extended downwards to expose the metallization layer 102.

Referring further to FIG. 1D, in the subsequent step, a conformal barrier/adhesive layer 116 is formed to a predefined thickness over all the exposed surfaces of the wafer, including the exposed part of the first-level metallization layer 102, the sidewalls of the dual-damascene hole 107 (FIG. 1B) in the dielectric layer 106, and the top surface of the dielectric layer 106, but not filling the dual-damascene hole 107 (FIG. 1B). Next, a metal, such as copper, is deposited in such a manner as to fill up all the remaining void portion of the dual-damascene hole 107 (FIG. 1B) and cover the topmost surface of the conformal barrier/adhesive layer 116 to a predefined thickness, whereby a conductive layer 118 is formed from the deposited metal.

Referring further to FIG. 1E, in the subsequent step, a chemical-mechanical polishing (CMP) process is performed to polish away all the portions of the conductive layer 118 and the conformal barrier/adhesive layer 116 that are laid above the topmost surface of the dielectric layer 106. Through this process, the topmost surface of the entire wafer is planarized, with the remaining part of the conformal barrier/adhesive layer 116 and the remaining part of the conductive layer 118 being left only in the previously formed dual-damascene hole 107 (FIG. 1B) in the dielectric layer 106. The combinedstructure of the remaining conductive layer 118 and the remaining conformal barrier/adhesive layer 116 constitute the intended dual-damascene structure. As shown, the dual-damascene structure is formed in such a manner as to penetrate through the dielectric layer 106 to come into electrical connection with the metallization layer 102. The wide upper part of the conductive layer 118 serves as the second-level metallization layer above the first-level metallization layer 102, while the narrow bottom part of the same serves as a metal plug interconnecting the second-level metallization layer to the first-level metallization layer 102. After this, a second topping layer 120 is formed over the entire top surface of the wafer to cover the conductive layer 118. The second topping layer 120 can prevent upward diffusion of the atoms in the conductive layer 118 into the dielectric layers (not shown) subsequently formed over the wafer.

One drawback to the foregoing method, however, is that the use of the RIE process to remove one part of the first topping layer 104 and expose the metallization layer 102 causes the surface of the exposed metallization layer 102 to be bombarded by the high energy ions used in the RIE process, thus causing the metal atoms in the metallization layer 102 to be knocked out and then deposited over the sidewalls of the narrow bottom part 112 of the dual-damascene hole 107. During subsequent thermal treatment, the deposited metal diffuses into the dielectric layer 106, thus affecting the overall electrical characteristics of the fabricated wafer. The resulting IC device may thus be defective and must be discarded. This decreases the yield rate of the wafer fabrication.

### SUMMARY OF THE INVENTION

It is therefore an objective of the present invention to provide a method for fabricating a dual-damascene structure in an integrated circuit, which can help eliminate the above-mentioned drawback of the prior art by forming the conformal barrier/adhesive layer before the use of the RIE process to expose the metallization layer.

In accordance with the foregoing and other objectives of the present invention, a new method for fabricating a dual-damascene structure in an integrated circuit is provided.

The method of the invention is characterized in that, after the dual-damascene hole is formed, a conformal barrier/adhesive layer is formed over all the sidewalls of the dual-damascene hole and covers the exposed part of the topping layer, but does not fill the dual-damascene hole. Subsequently, an anisotropic etching process, such as an RIE process, is performed to etch away the part of the conformal barrier/adhesive layer that is laid at the bottom of the dual-damascene hole directly over the topping layer and subsequently the underlying part of the topping layer until exposing the metallization layer. Finally, a conductive material, such as copper, is deposited into the remaining void portion of the dual-damascene hole. The deposited conductive material and the remaining part of the conformal barrier/adhesive layer in combination constitute the intended dual-damascene structure. By the method of the invention, the conformal barrier/adhesive layer serves a diffusion protective layer to the dielectric layers that can subsequently help prevent diffusion of the spluttering metal atoms from the metallization layer during the RIE process into the dielectric layer.

### BRIEF DESCRIPTION OF DRAWINGS

The invention can be more fully understood by reading the following detailed description of the preferred embodiments, with reference made to the accompanying drawings, wherein:

FIGS. 1A-1E are schematic, sectional diagrams used to depict the steps involved in a conventional method for fabricating a dual-damascene structure; and

FIGS. 2A-2G are schematic, sectional diagrams used to depict the steps involved in the method of the invention for fabricating a dual-damascene structure.

### DETAILED DESCRIPTION OF PREFERRED EMBODIMENTS

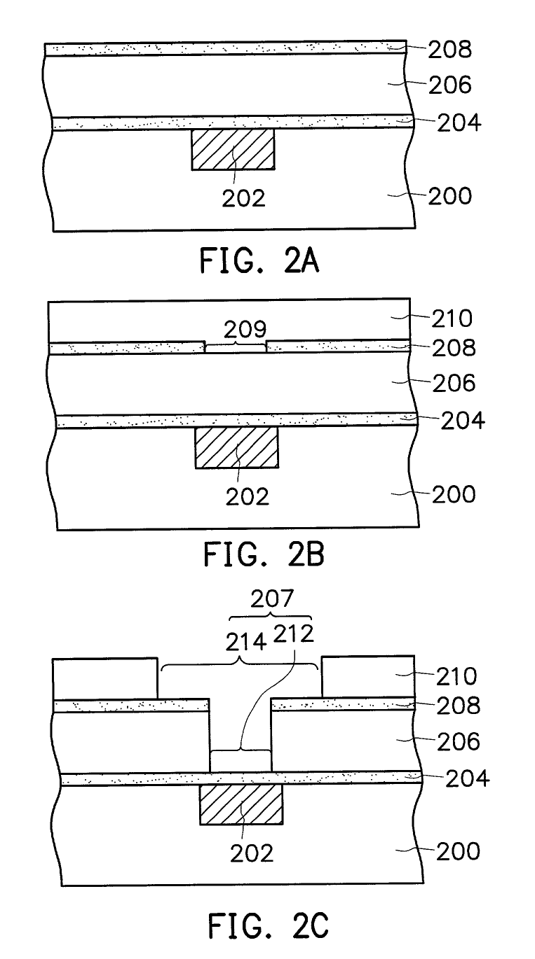

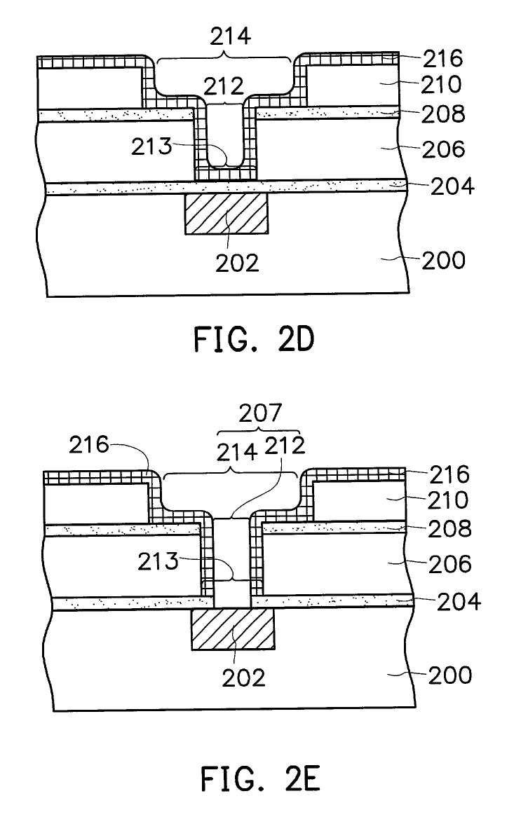

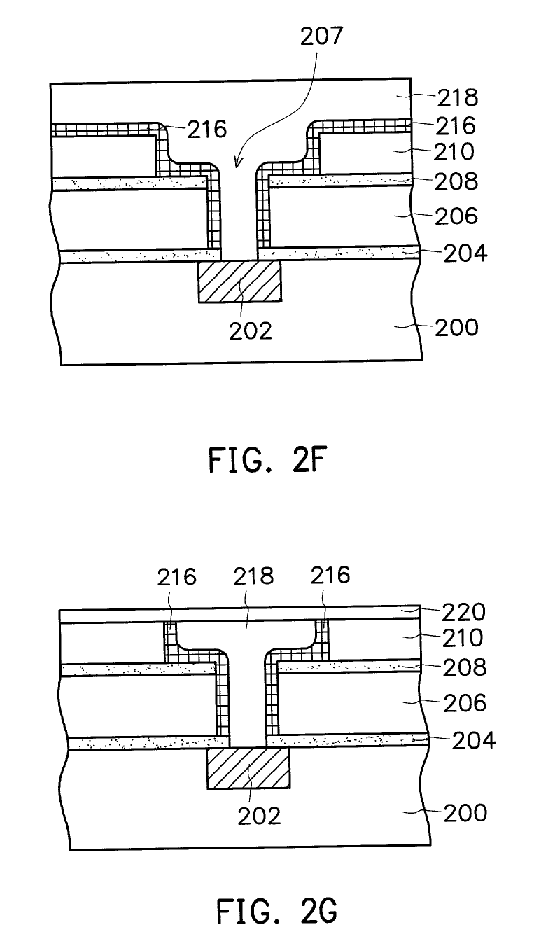

A preferred embodiment of the method according to the invention for fabricating a dual-damascene structure in an integrated circuit is disclosed in full details in the following with reference to FIGS. 2A-2G. For the purpose of this specification only, in the following description, the term “wafer” is used in an indefinite manner to refer to the entirety of either the raw wafer, the semi-fabricated wafer at any fabrication stage, or the fabricated wafer.

Referring first to FIG. 2A, in the first step, a semiconductor substrate 200 is prepared. Then, a first-level metallization layer 202 is formed, preferably from copper, at a predefined location in the substrate 200. Next, a first topping layer 204 is formed over the substrate 200 to cover the metallization layer 202, preferably from silicon nitride (SiNₓ) through a chemical-vapor deposition (CVD) process. After this, a first dielectric layer 206 is formed over the first topping layer 204, preferably from silicon oxide through a CVD process. Next, a chemical-mechanical polishing (CMP) process is performed for planarization of the top surface of the first dielectric layer 206 until the remaining part of the first dielectric layer 206 reaches a predefined thickness equal to the specified depth of the metal-plug portion of the intended dual-damascene structure. Next, an etch-end layer 208 is formed over the first dielectric layer 206, preferably from silicon nitride through a CVD process.

Referring next to FIG. 2B, in the subsequent step, a selective removal process, such as a photolithographic and etching process, is performed to remove a selected part of the etch-end layer 208 at a predefined location directly above the metallization layer 202, whereby an opening 209 is formed in the etch-end layer 208. After this, a second dielectric layer 210 is formed over the etch-end layer 208, preferably from silicon oxide through a CVD process. Next, a CMP process is performed for planarization of the top surface of the second dielectric layer 210 until the remaining part of the second dielectric layer 210 reaches a predefined thickness equal to the specified depth of the metallization-layer portion of the intended dual-damascene structure (i.e., the depth of the second-level metallization layer).

Referring further to FIG. 2C, in the subsequent step, a selective removal process, such as a photolithographic and etching process, is performed to etch away a selected part of the second dielectric layer 210 until exposing the etch-end layer 208, whereby a void portion 214 (serving as a metallization-layer trench) is formed in the second dielectric layer 210. The metallization-layer trench 214 is larger in width than the previously formed opening 209 (FIG. 2B) in the etch-end layer 208.

Subsequently, with the etch-end layer 208 serving as mask, an etching process is performed to etch away the unmasked part of the first dielectric layer 206 until reaching the first topping layer 204, whereby a void portion 212 (serving as a via hole) is formed in the first dielectric layer 206. The via hole 212 in the first dielectric layer 206 is smaller in width than the metallization-layer trench 214 in the second dielectric layer 210. The via hole 212 in the first dielectric layer 206 and the metallization-layer trench 214 in the second dielectric layer 210 in combination constitute a dual-damascene hole, as collectively designated by the reference numeral 207.

Referring next to FIG. 2D, in the subsequent step, a conformal barrier/adhesive layer 216 is formed to a predefined thickness over all the exposed surfaces of the wafer, including the exposed part of the first topping layer 204, all the sidewalls of the dual-damascene hole 207, and the topmost surface of the second dielectric layer 210, but not filling both the via hole 212 and the metallization-layer trench 214 of the dual-damascene hole 207. The conformal barrier/adhesive layer 216 is formed from a conformal barrier/adhesive material selected from the group consisting of tantalum, tantalum nitride, titanium, and titanium nitride. It is a characteristic part of the invention that the conformal barrier/adhesive layer 216 is formed prior to the removal of the exposed part of the first topping layer 204 overlying the metallization layer 202. The conformal barrier/adhesive layer 216 can serve both as a barrier structure for preventing metal atoms from diffusing into the first and second dielectric layers 206, 210, and as an adhesive structure for strengthening the bonding between the subsequently deposited metal in the dual-damascene hole 207 and the first and second dielectric layers 206, 210.

Referring further to FIG. 2E, in the subsequent step, an anisotropic etching process, such as an RIE (Reaction Ion Etching) process, is performed to etch away the bottom part 213 of the conformal barrier/adhesive layer 216 that is laid at the bottom of the via hole 212 of the dual-damascene hole 207 and subsequently the underlying part of the first topping layer 204 until exposing the metallization layer 202. Through this process, the via hole 212 of the dual-damascene hole 207 is further extended downwards to expose the metallization layer 202.

During the anisotropic etching process, those parts of the conformal barrier/adhesive layer 216 other than the bottom part 213 would also be subjected to the etching. However, due to step coverage, the bottom part 213 of the conformal barrier/adhesive layer 216 is particularly thinner than all the other parts of the conformal barrier/adhesive layer 216. Therefore, after the bottom part 213 is entirely etched away, the sidewalls of the dual-damascene hole 207 are nevertheless still covered by the remaining part of the conformal barrier/adhesive layer 216. In the event that the sidewall part of the conformal barrier/adhesive layer 216 is etched to such an extent as to expose either the first dielectric layer 206 or the etch-end layer 208, an additional selective deposition process can be performed to deposit the conformal barrier/adhesive material (i.e., tantalum, tantalum nitride, titanium, or titanium nitride) into those areas other than the area defined by the via hole 212 of the metallization-layer trench 214, so as to further build up the sidewall part of the conformal barrier/adhesive layer 216. With the protection from the conformal barrier/adhesive layer 216, the deposited metal atoms on the sidewalls of the dual-damascene hole 207 from the exposed metallization layer 202 during the RIE process hardly diffuse into the first and second dielectric layers 206, 210 as in the case of the prior art. The drawback of the prior art is thus eliminated by using the method of the invention.

Referring next to FIG. 2F, in the subsequent step, a metal, such as copper, is deposited in such a manner as to fill all the remaining void portion of the dual-damascene hole 207 and cover the topmost surface of the conformal barrier/adhesive layer 216 to a predefined thickness. Through this process, a conductive layer 218 is formed from the deposited metal.

Referring further to FIG. 2G, in the subsequent step, a surface removal process, such as a CMP process, is performed to remove all the portions of the conductive layer 218 and the conformal barrier/adhesive layer 216 that are laid above the topmost surface of the second dielectric layer 210. Through this process, the remaining part of the conformal barrier/adhesive layer 216 and the remaining part of the conductive layer 218 are left only in the previously formed dual-damascene hole 207 (FIG. 2E), and the combined structure of the remaining conductive layer 218 and the remaining conformal barrier/adhesive layer 216 serves as the intended dual-damascene structure. As show, the dual-damascene structure is formed in such a manner as to come into electrical connection with the first-level metallization layer 202. The wide upper part of the conductive layer 218 serves as the second-level metallization layer above the first-level metallization layer 202, while the narrow bottom part of the same serves as a metal plug interconnecting the second-level metallization layer to the first-level metallization layer 202. After this, a second topping layer 220 is formed over the entire top surface of the wafer to cover the conductive layer 218, preferably from silicon nitride through a CVD process. The second topping layer 220 can prevent the upward diffusion of the atoms in the conductive layer 218 into the dielectric layers (not shown) subsequently formed over the wafer. This completes the fabrication of the dual-damascene structure.

The invention is not limited to the above-mentioned dual-damascene structure, and can be applied to any semiconductor fabrication processes involving a damascene structure that is electrically connected to a metallization layer.

In conclusion, the method of the invention has the following advantages over the prior art.

(1) First, the method of the invention is characterized in that, after the dual-damascene hole is formed, a conformal barrier/adhesive layer is first formed on the bottom and sidewalls of the dual-damascene hole, which serves a diffusion protective layer for the first and second dielectric layers 206, 210 and can subsequently help prevent diffusion of the spluttering metal atoms from the metallization layer 202 during the RIE process into the first and second dielectric layers 206, 210. The resulting IC device is thus more reliable to operate. The yield rate of the wafer fabrication can thus be increased.

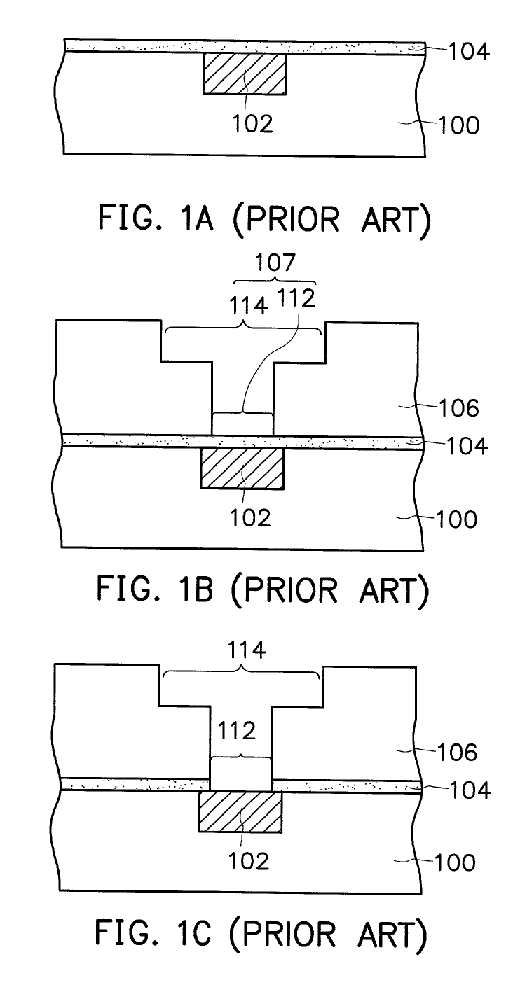

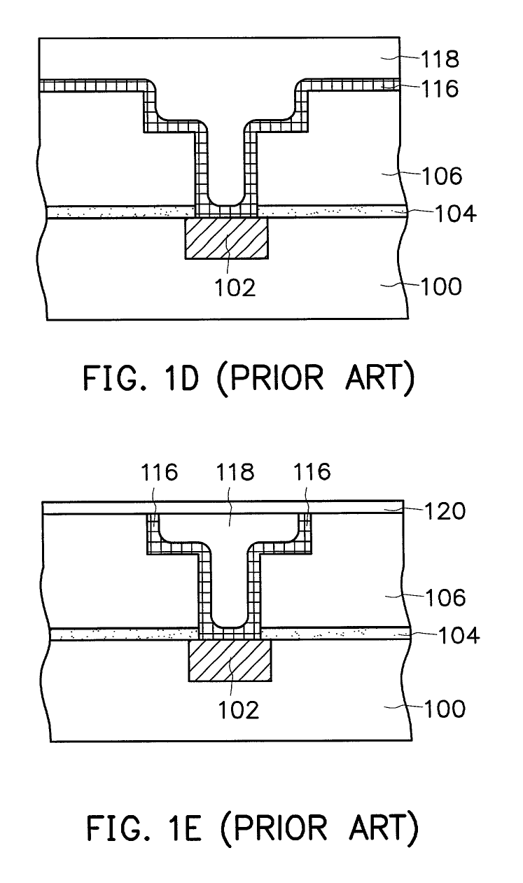

(2) Second, by the method of the invention, the resulting dual-damascene structure is in direct contact with the metallization layer 202, whereas by the prior art, the resulting dual-damascene structure is electrically connected via the bottom part of the conformal barrier/adhesive layer 116 to the first-level metallization layer 102 (see FIG. 1E). Therefore, by the invention, the electrical connection between the dual-damascene structure and the metallization layer 202 is lower in resistance than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a damascene structure in an integrated circuit constructed on a semiconductor substrate which is already formed with a metallization layer at a predefined location in the substrate and a topping layer formed over the substrate and covering the metallization layer, the method comprising the steps of:
forming a dielectric layer over the topping layer;
forming a damascene hole in the dielectric layer, which exposes the topping layer;
forming a conformal barrier/adhesive layer to a predefined thickness over all the sidewalls of the damascene hole, the exposed part of the topping layer, and the surface of the dielectric layer, but not filling the damascene hole;
performing an etching process to etch away the bottom part of the conformal barrier/adhesive layer that is laid at the bottom of the damascene hole directly over the topping layer and subsequently the underlying part of the topping layer until exposing the metallization layer; and
depositing a conductive material into the remaining void portion of the damascene hole, wherein the deposited conductive material and the remaining part of the conformal barrier/adhesive layer in combination constitute the intended damascene structure.

2. The method of claim 1, wherein the conformal barrier/adhesive layer is formed from a material selected from the group consisting of tantalum, tantalum nitride, titanium, and titanium nitride.

3. The method of claim 1, wherein the conductive material is copper.

4. The method of claim 1, wherein the etching process is an anisotropic etching process.

5. The method of claim 4, wherein the anisotropic etching process is an RIE process.

6. The method of claim 1, further comprising the step of forming a topping layer over the second dielectric layer.

7. A method for fabricating a dual-damascene structure in an integrated circuit constructed on a semiconductor substrate which is already formed with a metallization layer at a predefined location in the substrate and a topping layer formed over the substrate and covering the metallization layer, the method comprising the steps of:
forming a dielectric layer over the topping layer;
forming a dual-damascene hole in the dielectric layer, which exposes the topping layer;
forming a conformal barrier/adhesive layer to a predefined thickness over all the sidewalls of the dual-damascene hole, the exposed part of the topping layer, and the surface of the dielectric layer, but not filling the dual-damascene hole;
performing an etching process to etch away the bottom part of the conformal barrier/adhesive layer that is laid at the bottom of the dual-damascene hole directly over the topping layer and subsequently the underlying part of the topping layer until exposing the metallization layer; and
depositing a conductive material into the remaining void portion of the dual-damascene hole, wherein the deposited conductive material and the remaining part of the conformal barrier/adhesive layer in combination constitute the intended dual-damascene structure.

8. The method of claim 7, wherein the conformal barrier/adhesive layer is formed from a conformal barrier/adhesive material selected from the group consisting of tantalum, tantalum nitride, titanium, and titanium nitride.

9. The method of claim 7, wherein the conductive material is copper.

10. The method of claim 7, wherein the etching process is an anisotropic etching process.

11. The method of claim 10, wherein the anisotropic etching process is an RIE process.

12. The method of claim 7, further comprising the step of:
forming a topping layer over the second dielectric layer.

13. A method for fabricating a dual-damascene structure in an integrated circuit constructed on a semiconductor substrate which is already formed with a metallization layer at a predefined location in the substrate and a first topping layer formed over the substrate and covering the metallization layer, the method comprising the steps of:
forming a first dielectric layer over the first topping layer;
forming an etch-end layer over the first dielectric layer;
forming an opening at a predefined location in the etch-end layer directly above the metallization layer;
forming a first dielectric layer over the etch-end layer;
etching away a selected part of the second dielectric layer until reaching the etch-end layer to thereby form a metallization-layer trench in the first dielectric layer directly above the metallization layer;
etching away the part of the first dielectric layer that is not masked by the etch-end layer until exposing the first topping layer to thereby form a via hole in the first dielectric layer, wherein the via hole in the first dielectric layer and the metallization-layer trench in the second dielectric layer in combination constitute a dual-damascene hole;
forming a conformal barrier/adhesive layer to a predefined thickness over all the sidewalls of the dual-damascene hole and also over the surface of the second dielectric layer, but not filling the dual-damascene hole;
etching away the bottom part of the conformal barrier/adhesive layer that is laid at the bottom of the dual-damascene hole directly over the first topping layer and subsequently the underlying part of the first topping layer until exposing the metallization layer;
depositing a conductive material into the remaining void portion of the dual-damascene hole and over the conformal barrier/adhesive layer to a predefined thickness;
performing a surface removal process to remove those portions of the conductive layer and the conformal barrier/adhesive layer that are laid above the surface of the second dielectric layer, wherein the remaining part of the conductive layer and the remaining part of the conformal barrier/adhesive layer in combination constitute the intended dual-damascene structure; and
forming a second topping layer over the second dielectric layer to cover the dual-damascene structure.

14. The method of claim 13, wherein the conductive layer is formed from copper.

15. The method of claim 13, wherein the conductive layer is formed through a CVD process.

16. The method of claim 13, wherein the first topping layer is formed from silicon nitride.

17. The method of claim 13, wherein the conformal barrier/adhesive layer is formed from a conformal barrier/adhesive material selected from the group consisting of tantalum, tantalum nitride, titanium, and titanium nitride.

18. The method of claim 13, wherein the etching of the bottom part of the conformal barrier/adhesive layer and the underlying part of the first topping layer is carried out through an anisotropic etching process.

19. The method of claim 18, wherein the anisotropic etching process is an RIE process.
